(19) United States
(12) Patent Application Publication
(10) Pub. No.: US 2026/0090145 A1
(43) Pub. Date: Mar. 26, 2026

(54) LIGHT EMITTING DIODE AND LIGHT EMITTING DEVICE

(71) Applicant: QUANZHOU SANAN SEMICONDUCTOR TECHNOLOGY CO., LTD., Quanzhou (CN)

(72) Inventors: Zhongjie Yang, Quanzhou (CN); Guohua Zhang, Quanzhou (CN); Jingfeng Huang, Quanzhou (CN); Yongling LAN, Quanzhou (CN); Chung-Ying Chang, Quanzhou (CN)

(21) Appl. No.: 19/336,499

(22) Filed: Sep. 23, 2025

(30) Foreign Application Priority Data
Sep. 24, 2024 (CN) 202411337399.2

(51) Int. Cl. H10H 20/825; H01L 25/075; H10H 20/811

(52) U.S. Cl. CPC H10H 20/825; H10H 20/811; H10W 90/00

(57) ABSTRACT

Provided are a light emitting diode (LED) and a light emitting device. The LED includes a first semiconductor layer, an active layer and a second semiconductor layer, which are sequentially stacked in that order from bottom to top. The active layer includes AlₘGa₁₋ₘN barrier layers and AlₙGa₁₋ₙN well layer, which are alternately stacked periodically, and one AlₘGa₁₋ₘN barrier layer and one AlₙGa₁₋ₙN well layer is taken as one period to thereby form multiple periods. In at least one period of the multiple periods, a ratio of a thickness of the AlₙGa₁₋ₙN well layer to a thickness of the AlₘGa₁₋ₘN barrier layer is in a range of 1:3 to 1:8. By adjusting a thickness ratio of the AlₙGa₁₋ₙN well layer to the AlₘGa₁₋ₘN barrier layer, a combination efficiency of electrons and holes in a quantum well can be effectively improved, thus improving a luminous efficiency of the LED.

### CROSS-REFERENCE TO RELATED APPLICATION

This application claims the priority of Chinese Patent Application No. CN202411337399.2, filed on Sep. 24, 2024, which is herein incorporated by reference in its entirety.

### TECHNICAL FIELD

The present disclosure relates to the technical field of semiconductor devices, and particularly to a light emitting diode (LED) and light emitting device.

### BACKGROUND

In the technical field of ultraviolet (UV) LEDs, importance of the ultraviolet LEDs in applications such as medical disinfection, biological detection, and photocuring has become increasingly prominent with technological advancements. Particularly, LEDs in Ultraviolet B (UVB) and Ultraviolet C (UVC) bands have become the focus of research due to their high-energy characteristics. Currently, sapphire is widely used as a material of a substrate because of its excellent optical and thermal properties, providing a stable growth platform for LED chips. An active region of the UV LED typically employs a multiple-quantum-well structure composed of AlGaN quantum well layers and quantum barrier layers to enhance luminous efficiency and wavelength selectivity.

However, a difference in lattice constants between the sapphire substrate and the active region leads to stress issues that affect performance of the UV LED. To alleviate this problem, the industry often grows an AlN buffer layer on the sapphire substrate, which can effectively reduce stress and improve internal quantum efficiency. Nevertheless, a n-AlₓGa₁₋ₓN ohmic contact layer with a high-aluminum-composition in deep UV LEDs still faces challenges such as high defect density and significant lattice mismatch, which significantly impact the luminous efficiency of the deep UV LEDs.

### SUMMARY

In view of the defects and limitations of existing LEDs, the present disclosure provides an LED and a light emitting device to improve a luminous efficiency of current LEDs.

In a first aspect, an LED is provided, which includes: a first semiconductor layer, an active layer, and a second semiconductor layer, which are stacked sequentially in that order from bottom to top;
where the active layer includes AlₘGa₁₋ₘN barrier layers and AlₙGa₁₋ₙN well layers, which are alternately stacked periodically, where one layer of the AlₘGa₁₋ₘN barrier layers and one layer of the AlₙGa₁₋ₙN well layers is taken as one period to thereby form multiple periods, and 0<m<1 and 0<n<1; and
where in at least one period of the multiple periods, a ratio of a thickness of the AlₙGa₁₋ₙN well layer to a thickness of the AlₘGa₁₋ₘN barrier layer is in a range of 1:3 to 1:8.

In a second aspect, another LED is provided, which includes: a first semiconductor layer, an active layer, and a second semiconductor layer, which are stacked sequentially in that order from bottom to top;
where the active layer includes AlₘGa₁₋ₘN barrier layers and AlₙGa₁₋ₙN well layers, which are alternately stacked periodically, where one layer of the AlₘGa₁₋ₘN barrier layers and one layer of the AlₙGa₁₋ₙN well layers is taken as one period to thereby form multiple periods, and 0<m<1 and 0<n<1; and
where in each of the multiple periods, a thickness of the AlₘGa₁₋ₘN barrier layer is not more than 8 nm.

In a third aspect, a light emitting device is provided, which includes: a circuit board and multiple light emitting units disposed on the circuit board, where each of the multiple light emitting units includes the LED described above.

As mentioned above, the LED and the light emitting device of the present disclosure have the following beneficial effects.

By limiting the ratio of the thickness of the AlₙGa₁₋ₙN well layer to the thickness of the AlₘGa₁₋ₘN barrier layer in the active layer, or limiting the thickness of the AlₘGa₁₋ₘN barrier layer, the LED effectively improves an effective combination efficiency of electrons and holes in a quantum well, and improves a light emitting efficiency of the LED.

### BRIEF DESCRIPTION OF DRAWINGS

FIG. 1 illustrates a schematic structural view of an LED according to an embodiment 1 of the present disclosure.

FIG. 2 illustrates a schematic structural view of another LED according to the embodiment 1 of the present disclosure.

FIG. 3 illustrates a schematic structural view of yet another LED according to the embodiment 1 of the present disclosure.

FIG. 4 illustrates a schematic structural view of an LED according to an embodiment 2 of the present disclosure.

FIG. 5 illustrates a schematic structural view of a light emitting device according to an embodiment 3 of the present disclosure.

### DETAILED DESCRIPTION OF EMBODIMENTS

In a conventional deep UV LED, an ohmic contact layer is formed from nAlₓGa₁₋ₓN, where x>0.5, that is to say, the ohmic contact layer has a higher Al content. Firstly, AlGaN materials with a higher aluminum content are prone to defects in the growth process, which will capture carriers and reduce a luminous efficiency of the conventional deep UV LED. Secondly, there is a large difference in lattice constants between AlN layer and nAlₓGa₁₋ₓN ohmic contact layer with higher aluminum content, which will lead to lattice mismatch at an interface therebetween, further increase the generation of defects and affect the overall performance of the conventional deep UV LED.

Based on the background technology and the technical defects mentioned above, the present disclosure provides an LED and a light emitting device that overcome the above drawbacks and raise the emission efficiency of existing LEDs. It will be understood that the composition and thickness of every layer described herein can be analyzed by any suitable technique. Specific embodiments illustrating the present disclosure are detailed below.

### Embodiment 1

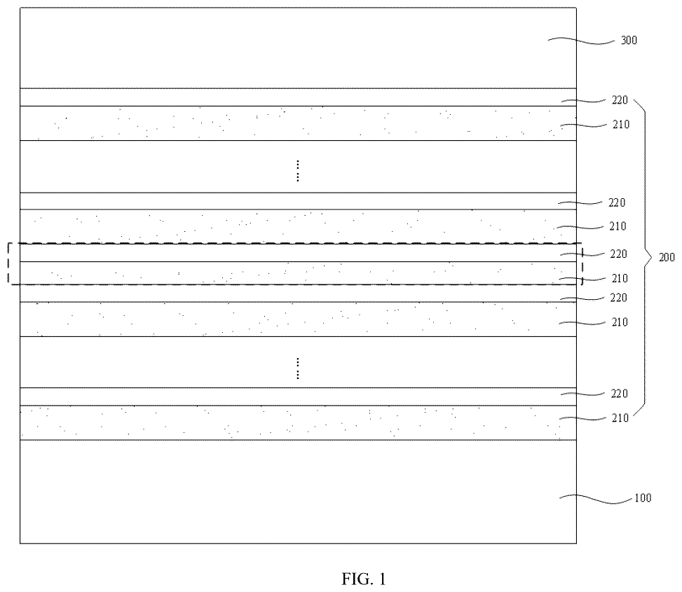

This embodiment provides an LED. As shown in FIG. 1, the LED includes a first semiconductor layer 100, an active layer 200, and a second semiconductor layer 300, which stacked sequentially in that order from bottom to top. The active layer 200 is a main region where the LED emits light. Electrons and holes recombine in this region and release energy in the form of light. The active layer 200 includes one or more periodic structures formed by alternately stacking a quantum barrier layer and a quantum well layer. Each period consists of one quantum barrier layer and one quantum well layer. In such a periodic structure, electrons and holes are confined in a quantum well, increasing their wave function overlap, enhancing the probability of radiative recombination, and thereby improving a luminous efficiency of the LED.

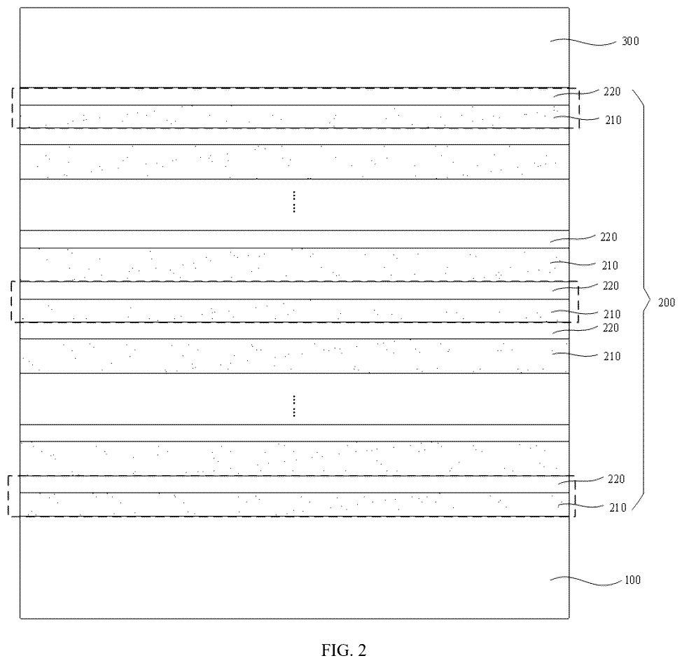

The active layer 200 of the LED in this embodiment includes AlₘGa₁₋ₘN barrier layers 210 with a total number of x and AlₙGa₁₋ₙN well layers 220 with a total number of y stacked alternately and periodically. One AlₘGa₁₋ₘN barrier layer 210 and one AlₙGa₁₋ₙN well layer 220 form one period, where 0<m<1, 0<n<1, 1≤x≤20, and 1≤y≤20. Values of x and y may be the same or different. A total number of periods can also be selected according to actual needs, for example, it can be 3 to 15 periods. The AlₘGa₁₋ₘN barrier layer 210 has a larger bandgap than the AlₙGa₁₋ₙN well layer 220. The LED in this embodiment is an UV LED. Materials of the quantum barrier layers and the quantum well layers in the active layer 200 are both exemplified by AlGaN. The alternating arrangement of the AlₘGa₁₋ₘN barrier layers 210 and the AlₙGa₁₋ₙN well layers 220 ensures that the light emitted after the recombination of electrons and holes is UV light with a wavelength of approximately 220 nm to 410 nm, and more specifically, between 240 nm and 370 nm. In this embodiment, in at least one period of the active layer 200, a thickness ratio of the AlₙGa₁₋ₙN well layer 220 to the AlₘGa₁₋ₘN barrier layer 210 is in a range of 1:3 to 1:8. A thickness ratio of the AlₙGa₁₋ₙN well layer 220 to the AlₘGa₁₋ₘN barrier layer 210 in each of the remaining periods is not specifically limited. In an embodiment, in at least one period, the thickness ratio of the AlₙGa₁₋ₙN well layer 220 to the AlₘGa₁₋ₘN barrier layer 210 may be, for example, 1:3, 1:4, 1:5, 1:6, 1:7, or 1:8. As shown in FIG. 1, only in one period of the active layer 200, the thickness ratio of the AlₙGa₁₋ₙN well layer 220 to the AlₘGa₁₋ₘN barrier layer 210 is in a range of 1:3 to 1:8 (this period is highlighted with a dashed box in FIG. 1). This period may be located near the first semiconductor layer 100, near the second semiconductor layer 300, or in the middle of the active layer 200, which is not specifically limited in this embodiment. As shown in FIG. 2, in at least two periods but not all periods of the active layer 200, the thickness ratio of the AlₙGa₁₋ₙN well layer 220 to the AlₘGa₁₋ₘN barrier layer 210 is in a range of 1:3 to 1:8 (the periods with thickness ratios within the above range are highlighted with dashed boxes in FIG. 2). The periods with the above thickness ratio of the well layer to the barrier layer may be dispersed or concentrated, which is not specifically limited in this embodiment. Similarly, the periods with the above thickness ratio may be located near the first semiconductor layer 100, near the second semiconductor layer 300, or in the middle of the active layer 200, which is not specifically limited in this embodiment. By limiting the thickness ratio of the AlₙGa₁₋ₙN well layer 220 to the AlₘGa₁₋ₘN barrier layer 210 in at least one period, this embodiment increases the recombination efficiency of electrons and holes in quantum wells, increases the number of photons generated during electron-hole recombination, improves a luminous brightness of the LED, and thereby enhances its luminous efficiency.

The first semiconductor layer 100 may be an N-type semiconductor layer that provides electrons through N-type doping. The N-type semiconductor layer may be formed by doping semiconductors with, for example, Si, Ge, Sn, Se, or, Te.

The second semiconductor layer 300 may be a P-type semiconductor layer that provides holes through P-type doping. The P-type semiconductor layer can be formed by doping semiconductors with, for example, Mg, Zn, Ca, Sr, or, Ba.

Alternatively, the first semiconductor layer 100 may be a P-type semiconductor layer, and the second semiconductor layer 300 may be an N-type semiconductor layer.

In an optional embodiment, as shown in FIGS. 1 and 2, in at least one period, a thickness ratio of the AlₙGa₁₋ₙN well layer 220 to the AlₘGa₁₋ₘN barrier layer 210 is in a range of 1:4 to 1:7. In an embodiment, in at least one period, the thickness ratio of the AlₙGa₁₋ₙN well layer 220 to the AlₘGa₁₋ₘN barrier layer 210 may be, for example, 1:4, 1:5, 1:6, or 1:7. By further limiting the thickness ratio of the AlₙGa₁₋ₙN well layer 220 to the AlₘGa₁₋ₘN barrier layer 210, the recombination efficiency of electrons and holes in the quantum wells is further enhanced, improving the luminous brightness of the LED and thereby further improving its luminous performance.

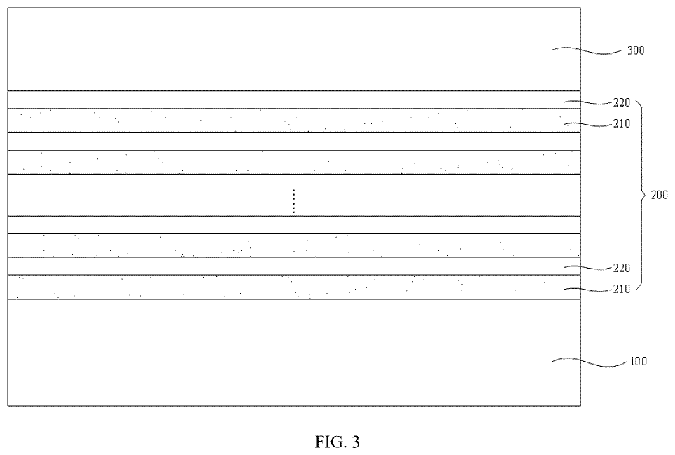

In an optional embodiment, as shown in FIG. 3, in each period, a thickness ratio of the AlₙGa₁₋ₙN well layer 220 to the AlₘGa₁₋ₘN barrier layer 210 is in a range of 1:3 to 1:8. In an embodiment, in each period, the thickness ratio of the AlₙGa₁₋ₙN well layer 220 to the AlₘGa₁₋ₘN barrier layer 210 may be, for example, 1:3, 1:4, 1:5, 1:6, 1:7, or 1:8. By maintaining a consistent thickness ratio of the AlₙGa₁₋ₙN well layer 220 to the AlₘGa₁₋ₘN barrier layer 210 in each period, the performance of the entire active layer 200 can be made more uniform, thereby improving the uniformity and reliability of the entire LED. A consistent thickness ratio helps optimize the recombination of electrons and holes in the quantum wells, thereby improving quantum efficiency and enhancing the luminous efficiency and brightness of the LED. By maintaining a consistent thickness ratio in each period, the emission wavelength of the LED can be more precisely controlled, which is particularly important for applications requiring specific spectral outputs, such as lasers or LEDs of specific colors. Maintaining a consistent thickness ratio in each period can reduce stress and defects caused by thickness variations, contributing to the long-term stability and lifespan of the LED.

In an optional embodiment, as shown in FIG. 3, in each period, a thickness ratio of the AlₙGa₁₋ₙN well layer 220 to the AlₘGa₁₋ₘN barrier layer 210 is in a range of 1:4 to 1:7. In an embodiment, in each period, the thickness ratio of the AlₙGa₁₋ₙN well layer 220 to the AlₘGa₁₋ₘN barrier layer 210 may be, for example, 1:4, 1:5, 1:6, or 1:7. By further limiting the thickness ratio to be consistent in each period, the performance consistency and reliability of the entire LED can be further improved. Maintaining a specific thickness ratio across all periods allows for more systematic optimization of the overall performance of the LED, such as luminous efficiency and spectral characteristics, ensuring that the performance of the entire LED is optimized. When all periods follow the same design rules, the manufacturing process may be simpler and easier to control, helping to improve production efficiency and reduce manufacturing variations.

In an optional embodiment, as shown in FIGS. 1 to 3, in one period, a sum of a thickness of the AlₘGa₁₋ₘN barrier layer 210 and a thickness of the AlₙGa₁₋ₙN well layer 220 is in a range of 7 nm to 10 nm. In an embodiment, in one period, the sum of the thickness of the AlₘGa₁₋ₘN barrier layer 210 and the thickness of the AlₙGa₁₋ₙN well layer 220 may be, for example, 7 nm, 7.5 nm, 8 nm, 8.5 nm, 9 nm, 9.5 nm, or 10 nm. As shown in FIG. 1, the sum of the thickness of the AlₘGa₁₋ₘN barrier layer 210 and the thickness of the AlₙGa₁₋ₙN well layer 220 in one period of the active layer 200 is in a range of 7 nm to 10 nm; A sum of thicknesses in each of other periods of the active layer 200 may be less than 7 nm or greater than 10 nm, which is not specifically limited in this embodiment. As shown in FIG. 2, in at least two periods of the active layer 200, a sum of a thickness of the AlₘGa₁₋ₘN barrier layer 210 and a thickness of the AlₙGa₁₋ₙN well layer 220 is in a range of 7 nm to 10 nm. Similarly, a sum of thicknesses in each of the remaining periods of the active layer 200 may be less than 7 nm or greater than 10 nm, which is not specifically limited in this embodiment. In this embodiment, when a total thickness of one period of the active layer 200 is within this range, it can effectively confine the movement of electrons and holes in the active layer 200, reduce the quantum-confined Stark effect, enhance the recombination probability of electrons and holes, and improve luminous efficiency and brightness. At the same time, by controlling the total thickness of the periodic structure, the recombination probability of electrons and holes can be further optimized, thereby further improving a luminous performance of the LED.

In an optional embodiment, as shown in FIGS. 1 to 3, in one period, a thickness of the AlₘGa₁₋ₘN barrier layer 210 is in a range of 6 nm to 8 nm. In an embodiment, the thickness of the AlₘGa₁₋ₘN barrier layer 210 may be, for example, 6 nm, 6.5 nm, 7 nm, 7.5 nm, or 8 nm. When the thickness of the AlₘGa₁₋ₘN barrier layer 210 is within the above range, it ensures the quality of the barrier layer on the one hand, and on the other hand, it helps improve hole injection efficiency. At the same time, it can effectively confine the movement of electrons and holes in the quantum wells, enhancing the recombination probability of electrons and holes, thereby improving luminous efficiency. An appropriate thickness helps improve the recombination of electrons and holes in the quantum wells, thereby enhancing luminous efficiency and brightness. When the thickness of the AlₘGa₁₋ₘN barrier layer 210 is less than 6 nm, it is too thin, and the quality may be poor. For example, it may not effectively block the flow of electrons and holes, leading to leakage between different regions of the light emitting diode. It may also fail to provide sufficient potential confinement, reducing the recombination efficiency of electrons and holes in the quantum wells, and may lead to a decrease in luminous efficiency. When the thickness of the AlₘGa₁₋ₘN barrier layer 210 is greater than 8 nm, it is too thick, causing electrons and holes to be confined in the barrier layer, resulting in recombination in the barrier layer and reducing the effective recombination efficiency in the quantum wells, thereby degrading luminous efficiency. Further, the thickness of the AlₘGa₁₋ₘN barrier layer 210 is in a range of 7 nm to 8 nm.

In an optional embodiment, as shown in FIGS. 1 to 3, in one period, a thickness of the AlₙGa₁₋ₙN well layer 220 is in a range of 1 nm to 2 nm. In an embodiment, in one period, the thickness of the AlₙGa₁₋ₙN well layer 220 may be, for example, 1 nm, 1.2 nm, 1.4 nm, 1.6 nm, 1.8 nm, or 2 nm. When the thickness of the well layer is in a range of 1 nm to 2 nm, it helps ensure the quality of the well layer on the one hand, and on the other hand, the well layer can effectively confine the three-dimensional movement of electrons and holes within it, enhancing the recombination probability of electrons and holes in the quantum wells, thereby improving the luminous efficiency of the LED. When the thickness of the well layer is less than 1 nm, it is too thin, and the quality may be poor. When the thickness of the well layer is greater than 2 nm, it is too thick, leading to a reduction in the number of holes, which also reduces the effective recombination efficiency of electrons and holes in the quantum wells, thereby degrading luminous efficiency.

In an optional embodiment, m≥0.5, and m >n. Since m≥0.5 in the barrier layer, it indicates a higher Al content in the barrier layer, which increases a bandgap width of the barrier layer, thereby enhancing the blocking effect on electrons and helping to effectively confine electrons in the quantum wells. A barrier layer with a higher Al content helps reduce electron leakage, allowing electrons to recombine more effectively with holes in the quantum wells, thereby improving the luminous intensity and efficiency of the LED. In an embodiment, 0.5≤m≤0.55. Since m>n, which means that the Al content in the barrier layer is higher than that in the well layer, it helps achieve better overlap of the wave functions of electrons and holes in the quantum wells, optimizing the recombination probability and improving luminous efficiency.

In an optional embodiment, as shown in FIGS. 1 to 3, along a direction from the first semiconductor layer 100 to the second semiconductor layer 300 (i.e., a bottom-up direction), an Al composition content m in the AlₘGa₁₋ₘN barrier layer 210 is constant, i.e., a content m of a component Al in the AlₘGa₁₋ₘN barrier layers is in a constant distribution. A constant Al composition content indicates that the barrier layer provides stable electron blocking throughout the structure, helping to maintain effective confinement of electrons in the quantum wells and optimizing the recombination process of electrons and holes. The constant distribution of the Al composition helps achieve uniform luminescent characteristics across the entire active layer 200, reducing luminescence non-uniformity caused by composition fluctuations and improving the overall luminescent quality of the LED. Due to the stable electron blocking effect of the barrier layer, the recombination of electrons and holes in the quantum wells is more effective, contributing to higher internal quantum efficiency and overall luminous efficiency of the LED. In semiconductor materials, abrupt changes in composition can cause lattice mismatch and stress concentration, while a constant Al composition helps reduce these stresses, thereby minimizing defect formation and improving the reliability and lifespan of the LED. During manufacturing, maintaining a constant Al composition distribution helps improve product consistency, reduce performance variations between batches, and enhance production efficiency and product quality.

In an optional embodiment, as shown in FIGS. 1 to 3, along the direction from the first semiconductor layer 100 to the second semiconductor layer 300 (i.e., the bottom-up direction), the Al composition content m in the AlₘGa₁₋ₘN barrier layer 210 gradually increases in a graded distribution, i.e., a content m of a component Al in the AlₘGa₁₋ₘN barrier layers increases gradually. That is, the Al content is higher in the barrier layer closer to the second semiconductor layer 300, which can effectively suppress electron mobility. As the Al composition gradually increases, a graded electron blocking layer is formed, helping to more effectively confine electron flow, reduce electron leakage into the P-type region, and thereby improve the efficiency of the LED. The graded distribution of the Al composition helps optimize the injection and recombination of electrons and holes, as electrons and holes can meet and recombine more effectively in the quantum wells, thereby enhancing luminous efficiency. In the active region of the LED, electron-hole recombination typically occurs in the quantum wells. The gradual increase in Al composition helps reduce leakage current, as the increased barrier layer can prevent non-radiative recombination of electrons and holes.

In an optional embodiment, as shown in FIGS. 1 to 3, along the direction from the first semiconductor layer 100 to the second semiconductor layer 300 (i.e., the bottom-up direction), the Al composition content n in the AlₙGa₁₋ₙN well layer 220 is constant, i.e., a content n of a component Al in the AlₙGa₁₋ₙN barrier layers is in a constant distribution. A constant Al composition distribution helps improve the recombination process of electrons and holes, enhancing luminous efficiency. Due to the constant Al composition in the well layer, electron and hole leakage in the quantum wells can be reduced, thereby improving the internal quantum efficiency and overall luminous efficiency of the LED. A constant Al composition content helps achieve uniform luminescent characteristics across the entire active layer 200, reducing luminescence non-uniformity caused by composition fluctuations and improving the overall luminescent quality of the LED.

In an optional embodiment, as shown in FIGS. 1 to 3, along the direction from the first semiconductor layer 100 to the second semiconductor layer 300 (i.e., the bottom-up direction), the Al composition content n in the AlₙGa₁₋ₙN well layer 220 gradually decreases in a graded distribution, i.e., a content n of a component Al in the AlₙGa₁₋ₙN barrier layers decreases gradually. That is, the Al composition content is higher in the well layer closer to the first semiconductor layer 100, which can increase the effective recombination probability of electrons and holes. The gradual decrease in Al composition content helps form a potential gradient, enabling more effective injection of electrons and holes into the quantum wells, thereby improving recombination efficiency and luminous performance. As the Al composition gradually decreases, strain caused by lattice mismatch can be reduced, as the lattice constant of each material layer is closer to that of the substrate or base material, helping to minimize dislocation and defect formation and improving the stability and lifespan of the LED.

### Embodiment 2

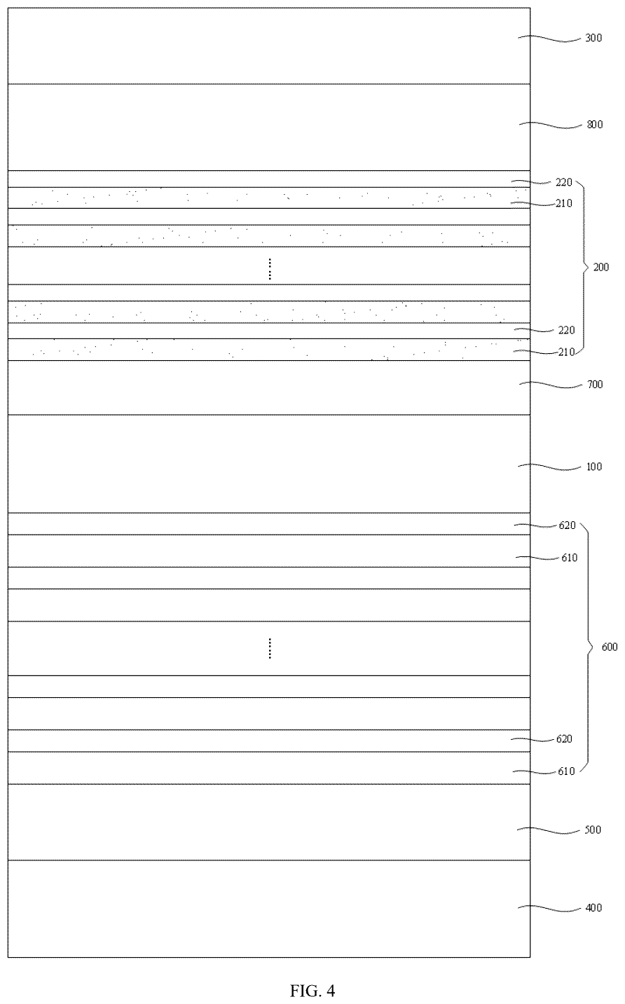

This embodiment provides an LED. As shown in FIG. 4, the LED includes a first semiconductor layer 100, an active layer 200, and a second semiconductor layer 300, which are sequentially stacked in that order from bottom to top. Similarly, the first semiconductor layer 100 may be an N-type semiconductor layer; the second semiconductor layer 300 may be a P-type semiconductor layer; the active layer 200 includes AlₘGa₁₋ₘN barrier layers 210 and AlₙGa₁₋ₙN well layers 220 stacked alternately and periodically, where one AlₘGa₁₋ₘN barrier layer 210 and one AlₙGa₁₋ₙN well layer 220 form one period, where 0<m<1 and 0<n<1. In each period, a thickness of the AlₘGa₁₋ₘN barrier layer 210 is no greater than 8 nm. Excessively thick barrier layers can cause electrons and holes to be confined within the barrier layers, resulting in a significant number of electrons and holes recombining in the barrier layers. This reduces the probability of electron-hole recombination in the quantum wells, leading to lower luminous efficiency. A thinner AlₘGa₁₋ₘN barrier layer 210 helps reduce the quantum-confined Stark effect in the quantum well structure, increases the probability of electron-hole recombination in the quantum wells, makes the recombination more efficient, and facilitates the conversion of more input electrical energy into light energy, thereby improving the overall luminous efficiency of the LED.

In an optional embodiment, in each period, a thickness of the AlₘGa₁₋ₘN barrier layer 210 is in a range of 6 nm to 8 nm. In an embodiment, in each period, the thickness of the AlₘGa₁₋ₘN barrier layer 210 may be, for example, 6 nm, 6.5 nm, 7 nm, 7.5 nm, or 8 nm. By further defining the thickness of the barrier layer, on the one hand, the quality of the barrier layer is ensured, and on the other hand, the hole injection efficiency is improved. Additionally, it optimizes the probability of electron-hole recombination in the quantum wells, enhancing the internal quantum efficiency and overall luminous efficiency of the LED. Further, in an embodiment, the thickness of the AlₘGa₁₋ₘN barrier layer 210 is in a range of 7 nm to 8 nm.

In an optional embodiment, in each period, a thickness of the AlₙGa₁₋ₙN well layer 220 is in a range of 1 nm to 2 nm. In an embodiment, in each period, the thickness of the AlₙGa₁₋ₙN well layer 220 may be, for example, 1 nm, 1.2 nm, 1.4 nm, 1.6 nm, 1.8 nm, or 2 nm. Within this specific thickness range, on the one hand, the quality of the well layer is ensured, and on the other hand, the quantum well layer can effectively confine the three-dimensional movement of electrons and holes within it, making electron-hole recombination in the quantum wells more efficient. This helps convert more input electrical energy into light energy, improving the overall luminous efficiency of the LED.

In an optional embodiment, in each period, a ratio of a thickness of the AlₙGa₁₋ₙN well layer 220 to a thickness of the AlₘGa₁₋ₘN barrier layer 210 is in a range of 1:3 to 1:8. In an embodiment, in each period, the ratio of the thickness of the AlₙGa₁₋ₙN well layer 220 to the thickness of the AlₘGa₁₋ₘN barrier layer 210 may be, for example, 1:3, 1:4, 1:5, 1:6, 1:7, or 1:8. By further defining the thickness ratio of the AlₙGa₁₋ₙN well layer 220 to the AlₘGa₁₋ₘN barrier layer 210 in each period, the electron-hole recombination efficiency in the quantum wells is further enhanced, improving the overall luminous performance of the LED. Further, in each period, the ratio of the thickness of the AlₙGa₁₋ₙN well layer 220 to the thickness of the AlₘGa₁₋ₘN barrier layer 210 in a range of 1:4 to 1:7. In an embodiment, in each period, the ratio of the thickness of the AlₙGa₁₋ₙN well layer 220 to the thickness of the AlₘGa₁₋ₘN barrier layer 210 may be, for example, 1:4, 1:5, 1:6, or 1:7.

In an optional embodiment, m≥0.5, and m>n. Since m≥0.5 in the AlₘGa₁₋ₘN barrier layer 210, it indicates a higher Al content in the barrier layer, which increases a bandgap width of the barrier layer and enhances the blocking effect on electrons. This helps effectively confine electrons in the quantum wells, further improving electron-hole recombination in the quantum wells and enhancing the overall luminous performance of the LED. Since m>n, the Al content in the barrier layer is higher than that in the well layer, which facilitates better overlap of electron and hole wavefunctions in the quantum wells, optimizes carrier recombination efficiency, and improves luminous efficiency. Further, in an embodiment, 0.5≤m≤0.55. With the Al composition within this range, electron-hole recombination in the quantum wells can be enhanced, as the band structure of the barrier layer helps balance the injection of electrons and holes, improving recombination efficiency.

In an optional embodiment, as shown in FIG. 4, the LED further includes a substrate 400. The substrate 400 provides mechanical support for the LED, ensuring stability during processing and use, and also helps conduct heat from the LED to the external environment, which is crucial for heat dissipation. The material of the substrate 400 may be selected from one or more of sapphire, SiC, GaAs, GaN, AlN, GaP, Si, ZnO, and MnO. In this embodiment, the substrate 400 is a sapphire substrate.

In an optional embodiment, as shown in FIG. 4, the LED further includes a buffer layer 500. The buffer layer 500 helps alleviate lattice mismatch between the substrate 400 and the first semiconductor layer 100, reducing dislocations and lattice defects, and improving the optoelectronic performance of the LED. A material of the buffer layer 500 may be selected from AlN, GaN, and SiC. In this embodiment, the material of the buffer layer 500 is AlN.

In an optional embodiment, as shown in FIG. 4, the LED further includes a transition layer 600 disposed between the buffer layer 500 and the first semiconductor layer 100. The transition layer 600 includes AlₓGa₁₋ₓN layers 610 and Al_{y}Ga_{1-y}N layers 620 stacked alternately and periodically, where one AlₓGa₁₋ₓN layer 610 and one Al_{y}Ga_{1-y}N layer 620 form one period, with 0<x<1, 0<y<1, and x≠y. The transition layer 600, by periodically alternating AlₓGa₁₋ₓN layers 610 and Al_{y}Ga_{1-y}N layers 620 with different Al compositions, helps alleviate stress caused by differences in lattice constants. It reduces lattice mismatch from the substrate 400 to the active layer 200, minimizing dislocations and other defects, and improving the overall quality of the LED.

In an optional embodiment, as shown in FIG. 4, the LED further includes an electron blocking layer 800 disposed between the active layer 200 and the second semiconductor layer 300. A primary function of the electron blocking layer 800 is to block electrons, preventing excessive diffusion of electrons into the second semiconductor layer 300, thereby improving the efficiency and performance of the LED. A material of the electron blocking layer 800 is one selected from P-type AlGaN, P-type GaN, and P-type InGaN. In this embodiment, the material of the electron blocking layer 800 is P-type AlGaN. When the Al composition is higher, it can increase the bandgap width, more effectively blocking electrons.

In an optional embodiment, as shown in FIG. 4, the LED further includes an electron control layer 700 disposed between the first semiconductor layer 100 and the active layer 200. The electron control layer 700, also referred to as an electron transport layer or N-type semiconductor layer, primarily controls the flow of electrons into the active layer 200 to optimize the injection and recombination processes of electrons and holes. A material of the electron control layer 700 may be one selected from N-type GaN, N-type AlGaN, and N-type InGaN. Since the LED in this embodiment is an UV LED, the material of the electron control layer 700 is N-type AlGaN, specifically Si-doped N-type AlGaN, to accommodate a higher bandgap.

### Embodiment 3

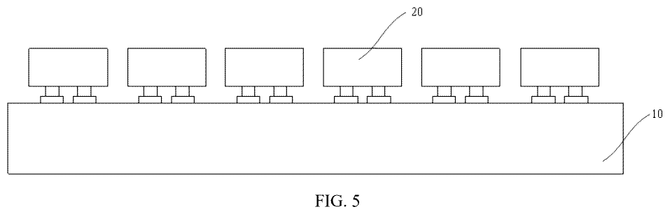

This embodiment provides a light emitting device. As shown in FIG. 5, the device includes a circuit board 10 and multiple light emitting units 20 disposed on the circuit board 10. Each of the light emitting units 20 includes the LED provided in the embodiment 1 or the embodiment 2. By defining the thickness ratio of the AlₙGa₁₋ₙN well layer 220 to the AlₘGa₁₋ₘN barrier layer 210 or by specifying the thickness of the AlₙGa₁₋ₙN well layer 220, the LEDs in the embodiment 1 or the embodiment 2 effectively enhance the recombination efficiency of electrons and holes in the quantum wells, thereby improving the luminous efficiency of the LEDs. By adopting the LEDs provided in the embodiment 1 or the embodiment 2, the light emitting units 20 in this embodiment contribute to improving the luminous efficiency of the light emitting device.

The above embodiments are merely illustrative of the principles and efficacy of the present disclosure and are not intended to limit the disclosure. Any person skilled in the art may modify or change the above embodiments without departing from the spirit and scope of the present disclosure. Accordingly, all equivalent modifications or changes made by those of ordinary skill in the art without departing from the spirit and technical ideas disclosed herein shall fall within the scope of protection of the claims of the present disclosure.

What is claimed is:

1. A light emitting diode (LED), comprising: a first semiconductor layer, an active layer, and a second semiconductor layer, which are stacked sequentially in that order from bottom to top;
wherein the active layer comprises AlₘGa₁₋ₘN barrier layers and AlₙGa₁₋ₙN well layers, which are alternately stacked periodically, where one layer of the AlₘGa₁₋ₘN barrier layers and one layer of the AlₙGa₁₋ₙN well layers is taken as one period to thereby form multiple periods, 0 <m<1, and 0<n<1; and
wherein in at least one period of the multiple periods, a ratio of a thickness of the AlₙGa₁₋ₙN well layer to a thickness of the AlₘGa₁₋ₘN barrier layer is in a range of 1:3 to 1:8.

2. The LED as claimed in claim 1, wherein in the at least one period of the multiple periods, the ratio of the thickness of the AlₙGa₁₋ₙN well layer to the thickness of the AlₘGa₁₋ₘN barrier layer is in a range of 1:4 to 1:7.

3. The LED as claimed in claim 1, wherein in each of the multiple periods, a ratio of a thickness of the AlₙGa₁₋ₙN well layer to a thickness of the AlₘGa₁₋ₘN barrier layer is in a range of 1:3 to 1:8.

4. The LED as claimed in claim 3, wherein in each of the multiple periods, the ratio of the thickness of the AlₙGa₁₋ₙN well layer to the thickness of the AlₘGa₁₋ₘN barrier layer is in a range of 1:4 to 1:7.

5. The LED as claimed in claim 1, wherein in one of the multiple periods, a sum of a thickness of the AlₘGa₁₋ₘN barrier layer and a thickness of the AlₙGa₁₋ₙN well layer is in a range of 7 nm to 10 nm.

6. The LED as claimed in claim 1, wherein in one of the multiple periods, a thickness of the AlₘGa₁₋ₘN barrier layer is in a range of 6 nm to 8 nm.

7. The LED as claimed in claim 1, wherein in one of the multiple periods, a thickness of the AlₙGa₁₋ₙN well layer is in a range of 1 nm to 2 nm.

8. The LED as claimed in claim 1, wherein m≥0.5, and m>n.

9. The LED as claimed in claim 1, wherein in a direction from the first semiconductor layer to the second semiconductor layer, a content m of a component Al in the AlₘGa₁₋ₘN barrier layers is in a constant distribution.

10. The LED as claimed in claim 1, wherein in a direction from the first semiconductor layer to the second semiconductor layer, a content m of a component Al in the AlₘGa₁₋ₘN barrier layers increases gradually.

11. The LED as claimed in claim 1, wherein in a direction from the first semiconductor layer to the second semiconductor layer, a content n of a component Al in the AlₙGa₁₋ₙN barrier layers is in a constant distribution.

12. The LED as claimed in claim 1, wherein in a direction from the first semiconductor layer to the second semiconductor layer, a content n of a component Al in the AlₙGa₁₋ₙN barrier layers decreases gradually.

13. The LED as claimed in claim 1, further comprising a substrate, wherein a transition layer is disposed between the substrate and the first semiconductor layer, the transition layer comprises AlₓGa₁₋ₓN layers and Al_{y}Ga_{1-y}N layers, which are alternately stacked periodically; and one layer of the AlₓGa₁₋ₓN layers and one layer of the Al_{y}Ga_{1-y}N layers is taken as one cycle, 0<x<1, 0<y<1, and x≠y.

14. The LED as claimed in claim 13, wherein a buffer layer is disposed between the substrate and the transition layer, and an electron blocking layer is disposed between the active layer and the second semiconductor layer.

15. An LED, comprising: a first semiconductor layer, an active layer, and a second semiconductor layer, which are stacked sequentially in that order from bottom to top;
wherein the active layer comprises AlₘGa₁₋ₘN barrier layers and AlₙGa₁₋ₙN well layers, which are alternately stacked periodically, where one layer of the AlₘGa₁₋ₘN barrier layers and one layer of the AlₙGa₁₋ₙN well layers is taken as one period to thereby form multiple periods, 0 <m<1, and 0<n<1; and
wherein in each of the multiple periods, a thickness of the AlₘGa₁₋ₘN barrier layer is not more than 8 nm.

16. The LED as claimed in claim 15, wherein in each of the multiple periods, the thickness of the AlₘGa₁₋ₘN barrier layer is in a range of 6 nm to 8 nm.

17. The LED as claimed in claim 15, wherein in one of the multiple periods, a thickness of the AlₙGa₁₋ₙN well layer is in a range of 1 nm to 2 nm.

18. The LED as claimed in claim 15, wherein in each of the multiple periods, a ratio of a thickness of the AlₙGa₁₋ₙN well layer to the thickness of the AlₘGa₁₋ₘN barrier layer is in a range of 1:3 to 1:8.

19. The LED as claimed in claim 15, wherein m≥0.5, and m>n.

20. A light emitting device, comprising: a circuit board and multiple light emitting units disposed on the circuit board, wherein each of the multiple light emitting units comprises the LED as claimed in claim 1.
